(19) United States
(12) Patent Application Publication
(10) Pub. No.: US 2026/0349017 A1
(43) Pub. Date: Nov. 5, 2026

(54) EXTRINSIC NOISE REMOVAL IN NOISE PRODUCTION TESTS

(71) Applicant: InvenSense, Inc., San Jose, CA (US)

(72) Inventors: Daniele Ghezzi, Cusano (IT); Andrea Giampiccolo, Pavia (IT)

(21) Appl. No.: 19/662,507

(22) Filed: Apr. 29, 2026

Related U.S. Application Data
(60) Provisional application No. 63/798,064, filed on May 1, 2025.

(51) Int. Cl. G01R 29/26; G01P 21/00

(52) U.S. Cl. CPC G01R 29/26; G01P 21/00

(57) ABSTRACT

An array of MEMS sensors is tested for noise at test equipment, and may experience extrinsic noise from sources such as the test equipment itself, other equipment, and the fabrication environment. The MEMS sensors are tested for noise in parallel and the resulting output data is transformed into the frequency domain. The resulting frequency-domain components are analyzed based on their average and standard deviation, with component signals having an average value more than a threshold number of standard deviations from an intrinsic component signal value such as zero removed from the overall composite noise signal. The remaining frequency-domain component signals correspond to the intrinsic noise, and are processed to mitigate the intrinsic noise during sensor operation such as by removing or compensating for the intrinsic noise.

### BACKGROUND

Numerous items such as smart phones, smart watches, tablets, automobiles, aerial drones, appliances, aircraft, exercise aids, and game controllers may utilize sensors such as microelectromechanical system (MEMS) sensors during their operation. In many applications, various types of motion sensors such as accelerometers and gyroscopes may be analyzed independently or together in order to determine varied information for particular applications. For example, gyroscopes and accelerometers may be used in gaming applications (e.g., smart phones or game controllers) to capture complex movements by a user, drones and other aircraft may determine orientation based on gyroscope measurements (e.g., roll, pitch, and yaw), and vehicles may utilize measurements for determining direction (e.g., for dead reckoning) and safety (e.g., to recognizing skid or roll-over conditions).

MEMS sensors include processing circuitry that is integrated into the sensor package for functions such as control of the sensor, signal processing, and communications with external devices. In production test environments, the MEMS sensors are subjected to various sources of noise originating from external sources such as handlers and test equipment, resulting in a variety of extrinsic noise types such as electromagnetic interference (EMI) and vibrations. This extrinsic noise can obscure and disrupt the measurement of intrinsic noise of a MEMS sensor during test operations, resulting in ineffective compensation or other processing used to minimize the intrinsic noise in the field. Current methodologies for noise measurement involve attempts to actively or passively control for the noise sources to minimize external noise effects, utilizing dampers, shields, and low-noise equipment. These methodologies do not capture the noise that is actually received at the MEMS sensor itself, and require constant updates to attempt to compensate for an ever-changing external noise environment.

### SUMMARY

In an embodiment of the present disclosure, a method for testing sensors comprises measuring a noise signal for an array of a plurality of sensors, transforming the noise signal to a frequency domain to generate a frequency domain noise signal, and identifying a plurality of component signals of the frequency domain noise signal. The method can further comprise determining a component value and a frequency for each component signal, determining a standard deviation of the component signals based on the respective component values and frequencies of the component signals, and identifying, as one or more extrinsic component signals, one or more of the component signals based on a comparison of the standard deviation to an average component value of the plurality of sensors at the frequency for the component signal. The method can further comprise removing the one or more extrinsic component signals from the frequency domain noise signal to generate a test signal and testing the plurality of sensors based on the test signal.

In an embodiment of the present disclosure, a test system for testing sensors comprises a test apparatus configured to test an array of a plurality of sensors, the test apparatus being configured to measure a noise signal for the array of the plurality of sensors. The test system can further comprise an analysis system coupled to the test apparatus and configured to transform the noise signal to a frequency domain to generate a frequency domain noise signal, identify a plurality of component signals of the frequency domain noise signal, and determine a component value and a frequency for each component signal. The analysis system can further be configured to determine a standard deviation of the component signals based on the respective component values and frequencies of the component signals and identify, as one or more extrinsic component signals, one or more of the component signals based on a comparison of the standard deviation to an average component value of the plurality of sensors at the frequency for the component signal. The analysis system can further be configured to remove the one or more extrinsic component signals from the frequency domain noise signal to generate a test signal, and test the plurality of sensors based on the test signal.

In an embodiment of the present disclosure, a system for testing sensors comprises an analysis system configured to receive a noise signal for an array of a plurality of sensors, wherein the analysis system is configured to receive the noise signal from the test apparatus, transform the noise signal to a frequency domain to generate a frequency domain noise signal, identify a plurality of component signals of the frequency domain noise signal, and determine a component value and a frequency for each component signal. The analysis system can be further configured to determine a standard deviation of the component signals based on the respective component values and frequencies of the component signals and identify, as one or more extrinsic component signals, one or more of the component signals based on a comparison of the standard deviation to an average component value of the plurality of sensors at the frequency for the component signal. The analysis system can be further configured to remove the one or more extrinsic component signals from the frequency domain noise signal to generate a test signal, and test the plurality of sensors based on the test signal.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative MEMS sensor test system in accordance with an embodiment of the present disclosure;

FIG. 2 depicts an exemplary system and process for performing parallelized extrinsic noise identification and removal in accordance with an embodiment of the present disclosure;

FIG. 3 depicts an exemplary noise frequency spectrum in accordance with an embodiment of the present disclosure;

FIG. 4 depicts exemplary time-domain signals depicting removal of intrinsic noise in accordance with an embodiment of the present disclosure;

FIG. 5 depicts exemplary steps for parallelized extrinsic noise identification and intrinsic noise compensation in accordance with an embodiment of the present disclosure; and

FIG. 6 depicts exemplary steps of frequency domain extrinsic noise component signal identification and removal in accordance with an embodiment of the present disclosure.

### DETAILED DESCRIPTION

As MEMS inertial sensors are used in an increasing number of end use applications, adherence to strict noise limits in those sensors becomes more critical for meeting a wide range of customer requirements, which in turn are based on meeting end user expectations for accuracy, and in many applications, safety requirements for end-use devices that utilize MEMS sensor output data for critical system operations. The present disclosure decouples intrinsic noise from extrinsic noise in testing procedures. This decoupling allows the intrinsic noise level to be accurately measured and compensated for at the sensor, and removes potential errors or inaccuracies due to extrinsic noise from external phenomenon from noise sources such as handlers, other equipment, environmental (e.g., temperature, humidity, airflow), and activity in the fabrication/manufacturing environment.

The systems and methods described herein are applied in production test equipment where multiple MEMS sensors are tested in parallel, such as at test equipment that is testing an array of MEMS sensors (e.g., on a wafer or otherwise configured for parallel testing). The intrinsic noise of a single MEMS sensor is generated by random sources that are not correlated with the homologous noise sources of other MEMS sensors tested in parallel. In the event of an external noise source (e.g., EMI and/or vibrations from external noise sources) that in turn results in extrinsic noise experienced at the MEMS sensors on the test equipment, all MEMS sensors tested in parallel will be affected by the extrinsic noise in the same or a very similar manner. The present disclosure utilizes parallelized testing and frequency domain statistical analysis to distinguish between noise component signals common among the tested parts (i.e., extrinsic noise) and those that are not (i.e., intrinsic noise). The systems and methods of the present disclosure calculate the result of a noise test by removing the extrinsic noise component signals from the acquired data, resulting in only consideration of intrinsic noise for estimation and compensation of each individual MEMS sensor. In an embodiment, the removed noise component signals are selected using a six-sigma criterion, ensuring that the compensation for the intrinsic noise at the MEMS sensor is suitable for safety-sensitive applications. In some embodiments, additional testing can be performed to further refine extrinsic noise sources, such as repeating the noise testing the array of MEMS sensors at multiple temperatures.

An exemplary noise test at test equipment for MEMS sensors includes sampling the output of each MEMS sensor of the array of MEMS sensors over a specified sampling time T, with the noise level determined as the RMS of the sampled data or through a similar method. In the sampling process, the MEMS sensor outputs are sampled for all parts tested with parallelism N. The data samples are then processed in the frequency domain, such as by applying a Fourier transform to analyze the resulting spectrum of the measured noise. The spectrum is processed such as for each part, including real and imaginary component signals. The resulting data is then analyzed in the frequency domain, such as by an average and standard deviation calculation. For each spectral component signal an average A among the N tested parts is calculated along with the standard deviation S. In the expected distribution, the average values are expected to be distributed around zero with a standard deviation of AS=S/sqrt(N). In the outlier removal, average values at frequencies that deviate from the average value of the intrinsic noise (e.g., at zero due to the intrinsic noise being uncorrelated) by more than a set criteria (e.g., six times the standard deviation or “six sigma”) are considered extrinsic, and the average value A corresponding to those extrinsic signals is removed from the overall spectral component signal. The resulting spectrum is used to calculate final intrinsic noise values for use such as in later noise removal or compensation operations. In this manner, the systems and methods of the present disclosure conservatively remove outlier spectral component signals that exhibit an unexpected distribution in average among the parts tested in parallel. The adoption of a particular test criterion (e.g., a six sigma criterion) ensures that the removed noise energy does not constitute part of the useful intrinsic signal for noise removal and compensation, thereby aligning the method with best practices in safety-sensitive markets.

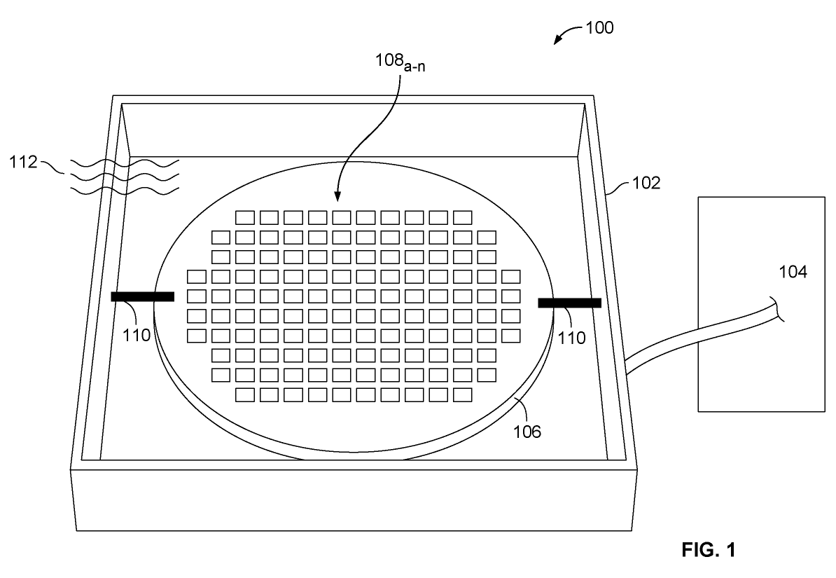

FIG. 1 shows an illustrative MEMS sensor test system in accordance with an embodiment of the present disclosure. Although FIG. 1 will be described in the context of a particular application and system components, it will be understood that the present disclosure may be utilized with a variety of test systems and applications. Although particular components are depicted and described in FIG. 1, it will be understood that components may be added, removed, substituted, or modified in accordance with the present disclosure. For example, for purposes of the present disclosure, simplified test equipment 102 for testing noise on an array of MEMS sensors is depicted and described, since the present disclosure is directed to signal analysis of the outputs of test systems that test for noise in multiple arrayed components, and thus, is broadly applicable to all outputs of noise test circuitry in a semiconductor fabrication or assembly environment. Further, although the present disclosure will discuss the noise test analysis and compensation of devices in the context of MEMS sensors such as MEMS inertial sensors (e.g., MEMS accelerometers and gyroscopes) which have particular strict requirements for accuracy and specification compliance, it will be understood that the present disclosure may be applied to other sensors and devices that experience intrinsic noise, such as other types of MEMS sensors (e.g., MEMS microphones, pressure sensors, etc.), piezoelectric micromachined ultrasound transducers (PMUTs), other types of motion sensors, or non-sensor electronic devices (e.g., integrated circuits, RF circuits, etc.).

In the embodiment of FIG. 1, a test system 100 includes test equipment 102, analysis system 104, wafer 106, an array of MEMS sensors 108ₐ₋ₙ, test probes 110, and extrinsic noise 112. Test equipment 102 includes test probes 110, depicted in a simplified form, and accommodates wafer 106 with test probes 110 connecting the test equipment 102 to the array of MEMS sensors 108ₐ₋ₙ on the wafer 106. Test equipment 102 is capable of providing and receiving signals to and from the MEMS sensors 108ₐ₋ₙ on the wafer 106 via the test probes 110 or other suitable signal connections (not depicted in FIG. 1). In embodiments signals are provided to the MEMS sensors 108ₐ₋ₙ in a manner such that noise can be assessed at each of the MEMS sensors 108ₐ₋ₙ and/or collectively over the entire array of MEMS sensors 108ₐ₋ₙ. Responsive signals representing the noise at the MEMS sensors 108ₐ₋ₙ (e.g., individually or collectively) are received back at the test equipment 102 and processed by analysis system 104. Test probes 110 are depicted in simplified form but may electrically connect to each of the MEMS sensors 108ₐ₋ₙ directly, such as via direct probe contacts, and/or may connect via circuitry of the MEMS sensors 108ₐ₋ₙ and/or of the wafer 106. In some embodiments (not depicted in FIG. 1), multiple MEMS sensors 108ₐ₋ₙ are arranged in an array for parallel testing after singulation, for example, at final test equipment.

The received noise signals are received by analysis system 104. Analysis system 104 may be implemented in whole or in part within the test equipment 102 and/or one or more other computing units such as computers, local servers, remote servers, etc. As described further herein, the analysis system 104 identifies extrinsic noise 112 that is received and sensed at the MEMS sensors 108ₐ₋ₙ and distinguishes this extrinsic noise 112 from intrinsic noise of the individual MEMS sensors of the array of MEMS sensors 108ₐ₋ₙ. The extrinsic noise 112 can be received from multiple sources external to the wafer 106, including the test equipment 102 itself, environmental sources, EMI sources, and mechanical vibration sources such as fabrication or assembly stations, other test equipment, material handlers, and other equipment and sources that are typically located within a semiconductor fabrication or assembly facility. Compared to extrinsic noise, the intrinsic noise of a single MEMS sensor 108 is generated by random sources that are not correlated with the homologous noise sources of other MEMS sensors 108ₐ₋ₙ tested in parallel. Based on this property, the extrinsic noise can be identified and removed from the noise measurements as described herein.

Each MEMS sensor 108 of an array of MEMS sensors 108ₐ₋ₙincludes micromechanical component signals (e.g., fabricated within a MEMS layer of the MEMS sensor) that move in response to an external force of interest (e.g., linear acceleration, angular velocity, pressure, etc.) relative to other components (e.g., one or more sense electrodes within the MEMS layer for in-plane sensing and/or one or more sense electrodes above or below the MEMS layer for out-of-plane sensing). The micromechanical components are housed within a cavity (e.g., at vacuum, atmospheric pressure, in communication with the external environment, or at another suitable pressure level based on sensor type and application) that is formed by coupling the MEMS layer to one or more other layers such a substrate layer and/or cap layer. In some embodiments, the MEMS sensor 108 is formed in a chip scale package, for example, with one or more layers removed or minimized in height and/or profile and capable of direct connection to external components. Each MEMS sensor 108 includes processing circuitry to operate the sensor, such as to perform control, signal processing, and communications functions. The processing may be internal to the MEMS sensor 108 (e.g., within a substrate layer and/or cap layer of the sensor), external to the sensor (e.g., on an adjacent or connected chip), and combinations thereof.

Processing circuitry may include one or more components providing processing based on the requirements of the MEMS sensor. In some embodiments, processing circuitry may include hardware control logic that may be integrated within a chip of a sensor (e.g., on a base substrate of a MEMS sensor 108 on an adjacent portion of a chip to the MEMS sensor) to control the operation of the MEMS sensor 108 and perform aspects of processing for the MEMS sensor 108. In some embodiments, the MEMS sensor 108 may include one or more registers that allow aspects of the operation of hardware control logic to be modified (e.g., by modifying a value of a register). In some embodiments, processing circuitry may also include a processor such as a microprocessor that executes software instructions, e.g., that are stored in a memory. The microprocessor may control the operation of the MEMS sensor 108 by interacting with the hardware control logic and processing signals received from MEMS sensor 108. The microprocessor may interact with other interconnected sensors in a similar manner. In some embodiments, some or all of the functions of the processing circuitry, and in some embodiments, of memory, may be implemented on an application specific integrated circuit (“ASIC”) and/or a field programmable gate array (“FPGA”).

The processing circuitry may convert signals received from the MEMS sensor 108 into appropriate measurement units (e.g., based on settings provided by other computing units communicating over a communication interface) and perform more complex processing to determine measurements such as orientation or Euler angles, and in some embodiments, to determine from sensor data whether a particular activity (e.g., walking, running, braking, skidding, rolling, etc.) is taking place. In some embodiments, some or all of the conversions or calculations may take place on the hardware control logic or other on-chip processing of the MEMS sensor 108. In some embodiments, certain types of information may be determined based on data from multiple measurements within a single MEMS sensor 108 and/or multiple MEMS sensors 108 in a process that may be referred to as sensor fusion. By combining information from a variety of sensors it may be possible to accurately determine information that is useful in a variety of applications, such as image stabilization, navigation systems, automotive controls and safety, dead reckoning, remote control and gaming devices, activity sensors, 3-dimenstional cameras, industrial automation, and numerous other applications.

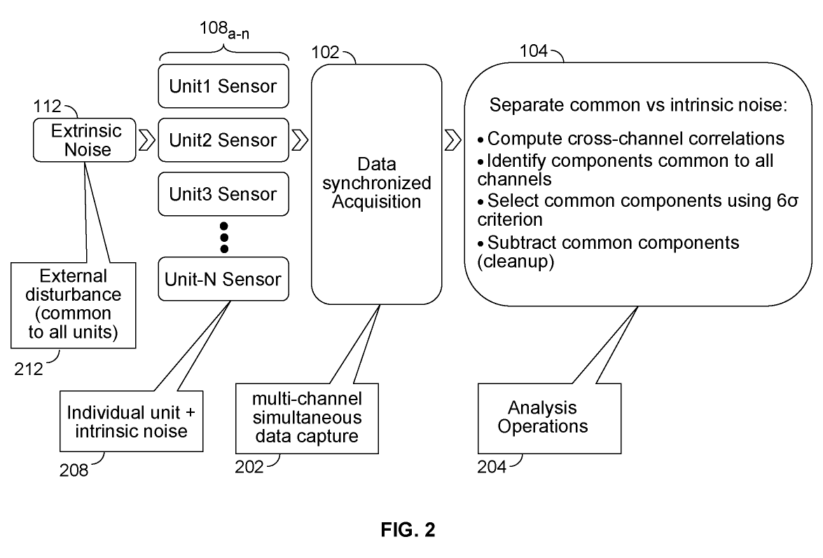

FIG. 2 depicts an exemplary system and process for performing parallelized extrinsic noise identification and removal in accordance with an embodiment of the present disclosure. Although FIG. 2 will be described in the context of a particular application and system components, it will be understood that the present disclosure may be utilized with a variety of test systems and applications. Although particular components are depicted and described in FIG. 2, it will be understood that components may be added, removed, substituted, or modified in accordance with the present disclosure. In the exemplary embodiment of FIG. 2, the system includes extrinsic noise 112, array of MEMS sensors 108ₐ₋ₙ (e.g., on a wafer 106 (not depicted in FIG. 2)), test equipment 102, and analysis system 104, each of has respective characteristics of operations including extrinsic noise characteristic 212, intrinsic noise characteristic 208, sensor test operations 202, and analysis operations 204.

Extrinsic noise 112 originates from one or more sources external to the wafer of MEMS sensors 108ₐ₋ₙ. In addition to having certain frequency content, these noise sources will be experienced in a manner that is common to each of the MEMS sensors 108ₐ₋ₙ on the wafer, in accordance with depicted by external noise characteristic 212 (e.g., EMI emissions, vibrations, etc. at particular frequencies). In this manner, extrinsic noise at each individual MEMS sensor 108ₐ₋ₙ should have virtually the same content relative to this external noise characteristic 212.

Each MEMS sensor 108 of the array of MEMS sensors 108ₐ₋ₙ has its own individual intrinsic noise characteristic 208 that is neither correlated to the intrinsic noise characteristic 208 of other MEMS sensors 108ₐ₋ₙ nor to the extrinsic noise characteristic 212. In this manner, the intrinsic noise characteristic 208 of a single MEMS sensor 108 is generated by random sources that are not correlated with the homologous noise sources of other MEMS sensors 108 of the array of MEMS sensors 108ₐ₋ₙ that are tested in parallel.

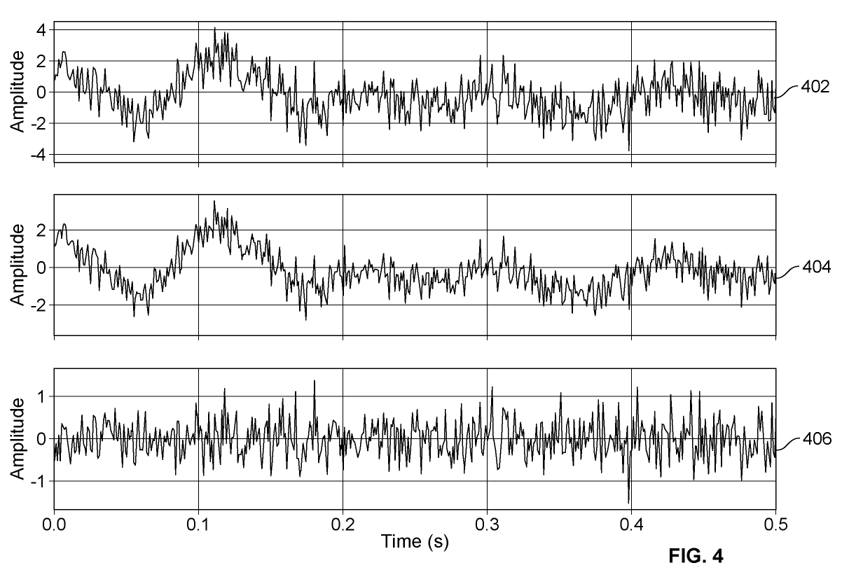

The test equipment 102 acquires noise signals during test operations 202 from the array of MEMS sensors 108ₐ₋ₙ. In some embodiments, the noise signals may be acquired multiple times under differing conditions, for example, under multiple different temperature conditions. In an embodiment this acquisition is performed in parallel and synchronized for each of the MEMS sensors 108ₐ₋ₙ individually during the test operations 202. In this manner, extrinsic noise 112 that is experienced at the MEMS sensors 108ₐ₋ₙ is captured at the same time and is synchronized. Noise signal acquisition test operations are thus performed in a multi-channel simultaneous data capture manner, with a respective noise signal acquired for each of the MEMS sensors 108ₐ₋ₙ over a time period T. The noise signals are acquired over the time T as a stream of samples having an amplitude and period between acquisitions. The acquisition time is such that frequency content from the extrinsic noise source 112, corresponding to the extrinsic noise characteristics 212, is captured for example as depicted in the upper two diagrams of FIG. 4 herein.

The noise signals are then provided to the analysis system 104 for identification and/or removal of the extrinsic noise 112 in accordance with analysis operations 204. In some embodiments the analysis system 104 may also perform compensation and/or apply other techniques for the removal of intrinsic noise once the extrinsic noise is separated, identified, and/or removed, or in some embodiments, the compensation may be performed by other systems or devices (e.g., at a later stage of the fabrication and assembly process) not depicted herein, but in the manner described herein based on the identified and/or removed extrinsic noise signals determined from analysis operations 204.

Although analysis operations 204 can include a variety of operations as will be understood by a person of ordinary skill in the art, in an embodiment the operations performed correspond to those depicted in bullet-point form with analysis system 104. Noise signals from parallel-sensed MEMS sensors 108ₐ₋ₙ may be acquired in a synchronized manner so that common behavior across the channels can be evaluated for the identification of extrinsic noise 112. The noise signals can be converted to a frequency domain such as by performing a Fourier transform on the noise signals to separate each component signal into real and imaginary parts. This facilitates analysis to be performed for individual frequency component signals. For corresponding frequency component signals across the multiple channels, the method can evaluate statistical characteristics to determine whether a given component signal behaves as intrinsic noise or as a common component signal shared among the channels. Because intrinsic noise is expected to be distributed around zero, a component signal having an average value that remains near zero may be treated as intrinsic, while a component signal having an average value displaced away from zero across the channels may be treated as common noise that is a candidate for removal as extrinsic noise.

In an exemplary embodiment, cross-channel correlations may then be computed to determine which portions of the measured data are common to the channels and which portions are not. Component signals that are common to all channels may be treated as corresponding to a common disturbance due to extrinsic noise signals 212, whereas intrinsic noise 208 may be treated as uncorrelated from one MEMS sensor 108ₐ₋ₙ to another. The common component signals may be selected according to suitable criterion such as a threshold multiple (e.g.¸ a six sigma criterion) of the standard deviation from the average value (e.g., zero) associated with the intrinsic noise. More particularly, when the average value of a component signal deviates from zero by more than the applicable threshold, that component signal may be identified as an unexpected component signal that is not attributable to intrinsic noise. Such a component signal may therefore be classified as a common component or extrinsic signal corresponding to an external disturbance affecting the channels in a common manner.

After the common component signals have been identified, those common component signals corresponding to the extrinsic noise characteristics 212 can be removed (e.g., subtracted) as a cleanup operation of the noise signals 202, resulting in a test signal for further use in assessing intrinsic noise of the MEMS sensors. In this manner, the frequency-domain data for each sensor may be cleaned by removing the identified common component signals (e.g., extrinsic noise characteristics 212), while retaining the remaining component signals that correspond to intrinsic noise (e.g., intrinsic noise characteristics).

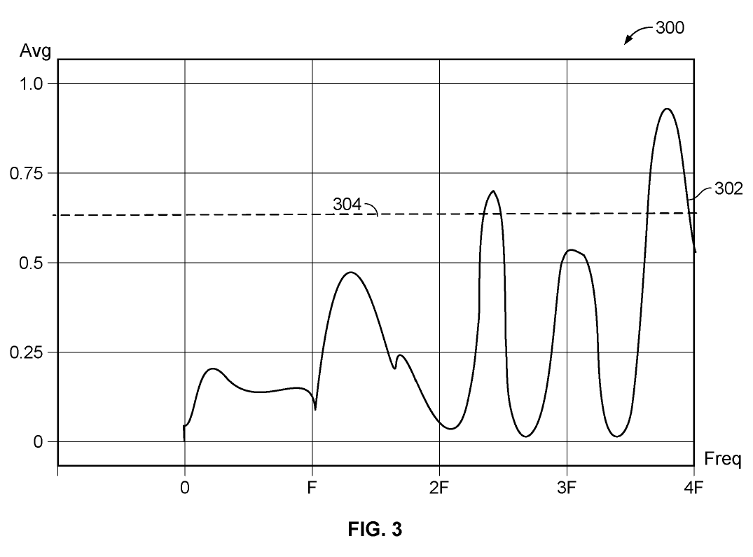

FIG. 3 depicts an exemplary noise frequency spectrum in accordance with an embodiment of the present disclosure. FIG. 3 illustrates an example manner in which spectral content may be evaluated to distinguish intrinsic noise from extrinsic noise in output data obtained from a plurality of MEMS sensors tested in parallel at test equipment. As shown, the graph 300 includes an ordinate that corresponds to average amplitude of component signals and an abscissa corresponds to the frequency of component signals. A frequency spectrum 302 is plotted on the graph 300, and a threshold 304 is provided to distinguish if a given average value of a spectral component among the sensors outputs at a given frequency is low (e.g., zero or close to zero, corresponding to intrinsic noise) or is above the threshold (e.g., corresponding to extrinsic noise). The threshold 304 may correspond to a statistical selection criterion, such as a six sigma criterion, used to determine whether a portion of the spectrum 302 is to be retained as intrinsic noise or rejected as extrinsic noise.

In the illustrated embodiment, the graph 300 represents average spectral behavior derived from sensor data collected during a noise test and processed in the frequency domain. The spectrum 302 may correspond to component signals identified from the measured MEMS sensor outputs, and the threshold 304 may represent a boundary used to distinguish expected spectral content from unexpected spectral content. In this manner, FIG. 3 schematically depicts how frequency-domain content may be screened so that spectral component signals corresponding to intrinsic sensor noise are preserved for subsequent noise calculation, while spectral component signals corresponding to common or external disturbance sources are excluded.

With respect to the portion of the spectrum 302 located below the threshold 304, that portion may be treated as intrinsic noise and retained. More particularly, spectral content within the threshold 304 may be regarded as satisfying the applicable criteria for expected noise behavior, such that the corresponding component signals are considered consistent with intrinsic noise of the sensors under test. Because such spectral content is not identified as statistically unexpected, it may be preserved in the resulting spectrum and used in calculating the final intrinsic noise value. Retaining this portion of the spectrum 302 may be desirable because it corresponds to the useful intrinsic noise information associated with the MEMS sensors themselves, rather than to an externally imposed disturbance.

With respect to the portion of the spectrum 302 greater than threshold 304, that portion may be treated as extrinsic noise and rejected. In particular, spectral content beyond the threshold 304 may be identified as failing the applicable criterion, for example by exceeding a six sigma-based threshold, and therefore may be classified as unexpected relative to the expected intrinsic-noise distribution. Such spectral content may accordingly be attributed to a disturbance source external to the sensors, such as environmental influence or test-equipment-induced noise, rather than to intrinsic sensor noise. For that reason, the corresponding signals may be dropped or removed from the spectrum 302 so that the remaining spectrum more accurately represents intrinsic noise of the sensors under test. thereby enabling a cleaned spectrum to be used for final noise evaluation.

FIG. 4 depicts exemplary time-domain signals depicting removal of intrinsic noise in accordance with an embodiment of the present disclosure. The set of plots of FIG. 4 depict example time-domain representations of sensor output data at successive stages of processing. In the illustrated embodiment, the plots are arranged from top to bottom to show how a measured signal may progress from an initial signal condition, through identification of common or extrinsic content, to a resulting signal after removal of extrinsic noise component signals identified in the frequency domain. As reflected in FIG. 4., the abscissa may correspond to time and the ordinate may correspond to amplitude. FIG. 4 thus provides a time-domain visualization of the effect of the disclosed frequency-domain analysis and cleanup operation on the sensor output data.

The upper plot 402 may represent an initial time-domain signal for a sensor unit before removal of extrinsic noise. In one example, the plotted waveform may include both an intrinsic noise contribution of the sensor and an extrinsic disturbance contribution that is common to multiple units tested in parallel. Such an initial waveform may exhibit frequency content movement attributable to noise coming from outside of the sensor, overlaid with oscillations attributable to intrinsic noise of the part. The frequency content from the extrinsic noise will be correlated with extrinsic noise at other MEMS sensors of an array of MEMS sensors, while the intrinsic noise is uncorrelated with either the extrinsic noise or intrinsic noise from other MEMS sensors. In that regard, the upper plot 402 may illustrate a composite signal in which external vibration or other environmental disturbance is superimposed on the intrinsic sensor noise.

The middle plot 404 may represent an intermediate time-domain signal corresponding to common behavior observed across multiple units tested simultaneously. More particularly, the middle plot 404 may reflect an averaged or otherwise common component signal derived from a plurality of sensor outputs acquired in parallel, such that the common extrinsic disturbance is emphasized relative to the uncorrelated intrinsic noise of the individual units. When multiple parts are affected by the same external noise shape, the average among all of the parts continues to follow that common low-frequency shape, even though intrinsic noise remains random from part to part. The middle plot 404 therefore illustrates the common time-domain component signal associated with the external perturbance that is later identified through spectral analysis.

The lower plot 406 represents a reconstructed time-domain signal of an exemplary sensor obtained after the frequency-domain analysis has been performed and identified extrinsic noise frequencies have been removed. In particular, after transforming the acquired data into the frequency domain, identifying spectral component signals corresponding to common noise, and removing those component signals according to the disclosed statistical criterion, the remaining signal may be transformed back into the time domain. The resulting reconstructed time-domain signal no longer shows the oscillation associated with the external disturbance and instead more closely reflects the intrinsic noise of the sensor. The lower plot 406 may therefore illustrate the cleaned time-domain result that is used to support calculation of the total intrinsic noise, for example by calculating the total power of the remaining noise for comparison with a specification or datasheet limit, removal, and/or compensation.

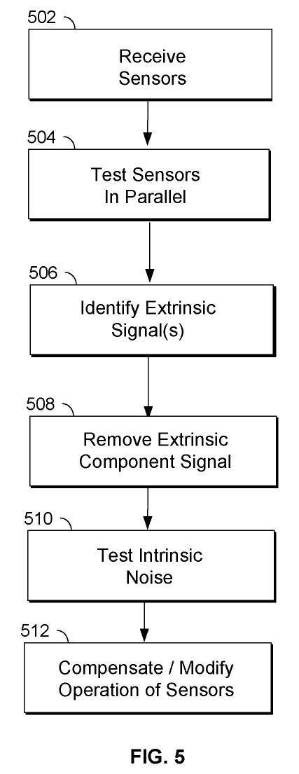

FIG. 5 depicts exemplary steps for parallelized extrinsic noise identification and intrinsic noise compensation in accordance with an embodiment of the present disclosure. Although particular steps are depicted in a certain order for FIG. 5, steps may be removed, modified, or substituted, and additional steps may be added in certain embodiments, and in some embodiments, the order of certain steps may be modified.

At step 502, test equipment receives MEMS sensors to be tested. In some embodiments, the MEMS sensors may include multiple parts arranged for production testing, such as MEMS sensors tested in parallel in an array, wafer-level configuration, final-test configuration, or other multi-unit test arrangement. The received sensors may be MEMS inertial sensors, such as MEMS accelerometers or gyroscopes, for which intrinsic noise is to be measured in the absence of an intended input signal. Processing may then continue to step 504.

At step 504, the MEMS sensors are tested in parallel. In some embodiments, output data from the MEMS sensors may be acquired simultaneously or synchronously so that common behavior across the MEMS sensors can be evaluated. Parallel testing may permit the process to distinguish between noise that is common among multiple MEMS sensors and noise that is intrinsic to individual MEMS sensors, because external disturbance tends to affect multiple MEMS sensors in the same manner while intrinsic noise is uncorrelated from one MEMS sensor to another. Processing may then continue to step 506.

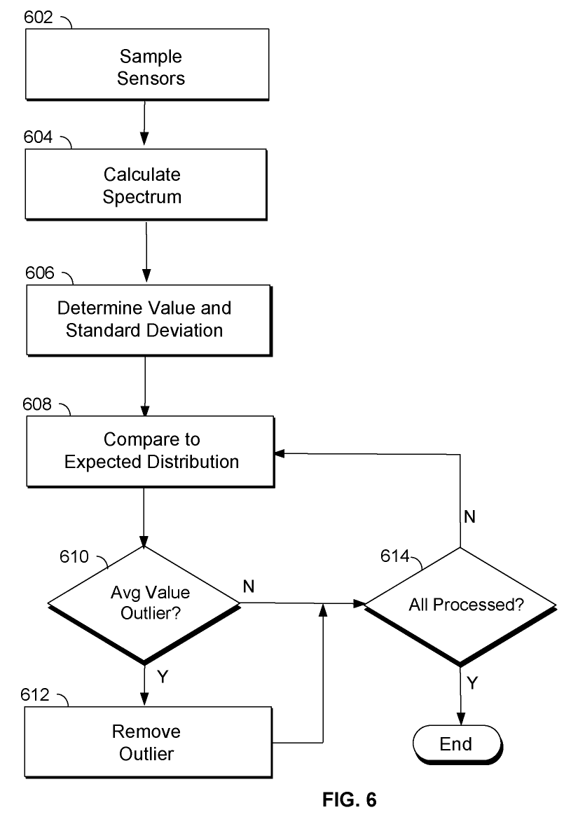

At step 506, one or more extrinsic component signals are identified for the array of MEMS sensors. The analysis system receives the data acquired from the MEMS sensors during the parallel testing, and performs operations including analyzing that data to determine whether one or more component signals correspond to noise coming from outside the MEMS sensors rather than intrinsic MEMS sensor noise. In some embodiments, the input data may be transformed into the frequency domain, statistical values may be calculated for corresponding component signals across multiple MEMS sensors, and component signals that satisfy an extrinsic-noise criterion may be identified as extrinsic signals. The output of step 506 may therefore include one or more identified frequency-domain component signals or other signal portions classified as extrinsic, as further described herein and in FIG. 6. Processing may then continue to step 508.

At step 508, the identified extrinsic component signal portions are removed, resulting in a test signal suitable for further analyzing intrinsic noise. In some embodiments, the inputs to this step may include the identified extrinsic signal or signals from step 506 and the measured MEMS sensor data from the parallel test. The operation performed at this step may include subtracting, suppressing, or otherwise excluding one or more identified extrinsic component signals from the MEMS sensor data, such as by removing selected frequency-domain component signals corresponding to the extrinsic noise in the frequency of domain. The output of step 508 may include cleaned MEMS sensor data, a cleaned spectrum, or another signal representation in which the identified extrinsic component signal contribution has been removed, as is further described herein and in FIG. 6. Processing may then continue to step 510.

At step 510, intrinsic noise is tested. In some embodiments, after the extrinsic contribution has been removed, the remaining data may be used to estimate intrinsic noise of the MEMS sensors more accurately. In some embodiments, the remaining spectral component signals may be integrated or otherwise combined to determine a total intrinsic noise value, which may then be compared with a specification limit, datasheet limit, or other acceptance criterion. In some embodiments, individual noise values may be measured (or accessed, if previously stored during acquisition of the initial noise signals) and modified based on the identified extrinsic noise signals. In some embodiments, an inverse transform may be performed on frequency-domain signal after removal of the extrinsic noise, to retrieve the time-domain intrinsic noise signals. However the intrinsic noise component signals are accessed or acquired, because the removed component signals correspond to common external perturbance rather than useful intrinsic signal content, the resulting intrinsic-noise test provides a stable and representative measurement of the intrinsic noise of the MEMS sensors themselves. Processing may then continue to step 512.

At step 512, operation of the MEMS sensors is compensated or modified based on the testing results. In some embodiments, the intrinsic-noise measurement obtained after removal of extrinsic noise may be used to determine whether a given MEMS sensor, group of MEMS sensors, or tested lot satisfies a required performance level. Additionally or alternatively, the resulting information may be used to adjust calibration, compensation, pass/fail disposition, or another operational parameter associated with the MEMS sensors or a system incorporating the MEMS sensors. In this manner, the process may extend beyond noise identification and cleanup to a downstream operational action based on the improved intrinsic noise estimation.

FIG. 6 depicts exemplary steps of frequency domain extrinsic noise component signal identification and removal in accordance with an embodiment of the present disclosure. Although particular steps are depicted in a certain order for FIG. 6, steps may be removed, modified, or substituted, and additional steps may be added in certain embodiments, and in some embodiments, the order of certain steps may be modified.

At step 602, the MEMS sensors are sampled. In some embodiments, this step may include sampling output data from a parallelized array of MEMS sensors, such that multiple MEMS sensor units are tested simultaneously. The sampled data may correspond to MEMS sensor output measured in a no-input condition, thereby capturing noise present in the MEMS sensor output. By acquiring the data in parallel and in a synchronized manner, the process may preserve information that permits later identification of signal content common to multiple MEMS sensors. Processing may then continue to step 604.

At step 604, a spectrum is calculated for the sampled data. In some embodiments, the sampled time-domain data for each MEMS sensor may be transformed into the frequency domain, for example by applying a Fourier transform. This operation may produce a plurality of spectral component signals for each MEMS sensor, thereby permitting the analysis system to evaluate the data on a component signal-by-component signal basis as a function of frequency rather than only in the aggregate time-domain waveform. Processing may then continue to step 606.

At step 606, the process determines averages and standard deviation for the component signals. In some embodiments, for each frequency-domain component signal, the algorithm may effectively perform the plotting operation by determining a representative value, such as an average value across the MEMS sensors under test, together with a standard deviation indicative of variation among the component signals. This step may therefore generate the statistical quantities used to assess whether a given frequency-domain component signal is consistent with intrinsic noise distributed around zero or instead suggests a common disturbance affecting the MEMS sensors in parallel and thus corresponding to extrinsic noise. Processing may then continue to step 608.

At step 608, the determined value is compared to an expected distribution. In some embodiments, the expected distribution may correspond to intrinsic noise behavior, which is expected to be centered around zero with a spread characterized by the standard deviation. The frequency locations of average values for given frequency-domain component signals may therefore be evaluated relative to the expected distribution to determine whether that component signal remains within an expected intrinsic-noise range or departs from that range in a statistically significant manner. Processing may then continue to step 610.

At decision step 610, the process determines whether the average value is an outlier. In some embodiments, the algorithm may determine whether an average value at a frequency associated with noise satisfies a criterion such as by exceeding an applicable threshold, such as a six sigma threshold. If the frequency associated average value is not an outlier, the component signal may be retained as part of the intrinsic-noise estimation. If the frequency associated with a particular average value is an outlier, the process may proceed to removal of that component signal as corresponding to extrinsic noise. Processing may then continue to step 612.

At step 612, outlier signals corresponding to extrinsic noise are removed. In some embodiments, when a frequency-domain component signal has been identified as an outlier, that component signal may be removed from further calculation of the total noise. Such removal may include subtracting, suppressing, or otherwise excluding the corresponding spectral component signal from the MEMS sensor data so that the remaining spectrum more accurately reflects intrinsic noise rather than common external disturbance. Processing may then continue to step 614.

At decision step 614, the process determines whether all component signals have been processed, in which case the resulting test signal is suitable for further analyzing intrinsic noise. In some embodiments, the algorithm may iterate through the frequency-domain component signals sequentially, repeating the comparison and outlier analysis for each component signal in the spectrum. If additional component signals remain to be processed, the method may return for continued evaluation. If all component signals have been processed, the method may end at which point the remaining spectral content may be used to calculate the intrinsic noise of the MEMS sensors under test.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A method for testing sensors, comprising:
measuring a noise signal for an array of a plurality of sensors;
transforming the noise signal to a frequency domain to generate a frequency domain noise signal;
identifying a plurality of component signals of the frequency domain noise signal;
determining a component value and a frequency for each component signal;
determining a standard deviation of the component signals based on the respective component values and frequencies of the component signals;
identifying, as one or more extrinsic component signals, one or more of the component signals based on a comparison of the standard deviation to an average component value of the plurality of sensors at the frequency for the component signal;
removing the one or more extrinsic component signals from the frequency domain noise signal to generate a test signal; and
testing the plurality of sensors based on the test signal.

2. The method of claim 1, further comprising:
repeating each of the steps of claim 1 at each of a plurality of temperatures to generate a plurality of test signals; and
performing the testing of the plurality of sensors based on the plurality of test signals.

3. The method of claim 1, wherein identifying the one or more extrinsic component signal comprises:
determining which of the component signals have a component value that meets a criteria;
selecting, from the component signals that have a component value that meets the criteria, a component signal that is closest to a zero frequency as an intrinsic component signal; and
measuring the standard deviation from the intrinsic component signal.

4. The method of claim 3, wherein the component value is an average and the criteria is a threshold.

5. The method of claim 3, wherein identifying one or more of the component signals based on the standard deviation comprises determining whether the one or more component signals are at least a multiple of the standard deviation away from the intrinsic component signal.

6. The method of claim 5, wherein the multiple of the standard deviation is six standard deviations t.

7. The method of claim 1, wherein the noise signal corresponds to a noise of the plurality of sensors while the sensors are not sensing an external phenomenon.

8. The method of claim 7, wherein the plurality of sensors comprise a plurality of inertial sensors, and wherein the external phenomenon comprises a linear acceleration or an angular velocity.

9. The method of claim 7, wherein the array of sensors are arranged on a shared wafer.

10. The method of claim 1, wherein the one or more extrinsic components correspond to a noise source that is external to the plurality of sensors.

11. The method of claim 10, wherein the noise source that is external to the plurality of sensors comprises a test equipment performing the testing.

12. The method of claim 10, wherein the noise source comprises an extrinsic noise source.

13. The method of claim 12, wherein the noise source comprises EMI or vibrations.

14. The method of claim 1, wherein measuring the noise signal comprises simultaneously acquiring output data from each of the plurality of sensors.

15. The method of claim 1, wherein calculating the component value comprises calculating, for each component, an average of corresponding component amplitudes for the plurality of sensors.

16. The method of claim 1, wherein removing the one or more extrinsic component signals comprises subtracting, from a frequency-domain signal of each sensor, a component corresponding to the one or more extrinsic component signals.

17. The method of claim 1, further comprising performing an inverse transform on the test signal to generate a time-domain signal for each sensor.

18. The method of claim 1, wherein each of the plurality of sensors comprises a microelectromechanical system (MEMS) inertial sensor.

19. A test system for testing sensors, comprising:
a test apparatus configured to test an array of a plurality of sensors, the test apparatus being configured to measure a noise signal for the array of the plurality of sensors; and
an analysis system coupled to the test apparatus and configured to:
transform the noise signal to a frequency domain to generate a frequency domain noise signal;
identify a plurality of component signals of the frequency domain noise signal;
determine a component value and a frequency for each component signal;
determine a standard deviation of the component signals based on the respective component values and frequencies of the component signals;
identify, as one or more extrinsic component signals, one or more of the component signals based on a comparison of the standard deviation to an average component value of the plurality of sensors at the frequency for the component signal;
remove the one or more extrinsic component signals from the frequency domain noise signal to generate a test signal; and
test the plurality of sensors based on the test signal.

20. A system for testing sensors, comprising:
an analysis system configured to receive a noise signal for an array of a plurality of sensors, wherein the analysis system is configured to:
receive the noise signal from the test apparatus;
transform the noise signal to a frequency domain to generate a frequency domain noise signal;
identify a plurality of component signals of the frequency domain noise signal;
determine a component value and a frequency for each component signal;
determine a standard deviation of the component signals based on the respective component values and frequencies of the component signals;
identify, as one or more extrinsic component signals, one or more of the component signals based on a comparison of the standard deviation to an average component value of the plurality of sensors at the frequency for the component signal;
remove the one or more extrinsic component signals from the frequency domain noise signal to generate a test signal; and
test the plurality of sensors based on the test signal.
